(19) United States
(12) Patent Application Publication
(10) Pub. No.: US 2014/0308460 A1
(43) Pub. Date: Oct. 16, 2014

(54) CONDUCTIVE PATTERN FORMATION METHOD

(71) Applicant: SHOWA DENKO K.K., Minato-ku, Tokyo (JP)

(72) Inventor: Hiroshi Uchida, Chiba (JP)

(73) Assignee: SHOWA DENKO K.K., Minato-ku, Tokyo (JP)

(21) Appl. No.: 14/359,598

(22) PCT Filed: Nov. 26, 2012
(86) PCT No.: PCT/JP2012/007555

§ 371 Date: May 21, 2014

(30) Foreign Application Priority Data
Nov. 25, 2011 (JP) 2011-257345

(51) Int. Cl. H05K 3/10

(52) U.S. Cl. CPC H05K 3/105
USPC 427/557; 427/98.4

(57) ABSTRACT

Provided is a conductive pattern formation method capable of improving conductivity of a conductive pattern. An ink layer 12 is formed by printing a composition (ink) containing metal oxide particles and a reducing agent, and/or metal particles, on a surface of a substrate 10 and the ink layer 12 is heated by photo irradiation or microwave irradiation so that conductivity is expressed on the heated portion and the ink layer 12 is converted into a conductive layer 14. Metal particles and/or metal oxide particles are heated quickly in a short time and air bubbles are generated during photo irradiation or microwave irradiation and voids are generated inside the conductive layer 14, and thus the conductive layer 14 is pressurized by an appropriate pressing machine 16 to crush the voids to improve conductivity of the conductive layer 14 before obtaining a conductive pattern 18. When the conductive layer 14 is pressurized, an insulating protection film 20 can simultaneously be pressure-sealed on the surface of the substrate on which the conductive layer 14 is formed.

### TECHNICAL FIELD

The present invention relates to an improved conductive pattern formation method.

### BACKGROUND ART

Conventionally a method for forming a circuit pattern by the lithography method which combines copper foil and a photoresist has generally been used as a technology to produce a fine circuit pattern, but this method requires a larger number of processes and the cost of a waste water/waste liquid treatment is expensive and thus, improvement of the method is desired in view of environmental issues. Further, a technique using a photolithography method by which a metallic thin film produced by the heating evaporation method or the sputtering method is processed to form pattern is known. However, a vacuum environment is indispensable for the heating evaporation method and the sputtering method and the cost will be very high and thus, if the technique is applied to a wiring pattern, it is difficult to reduce the manufacturing cost.

Thus, a technology to produce a circuit by printing by using metal ink (including ink containing a metal oxide which can be reduced to a metal using a reducing agent) is proposed. Circuit forming technology by printing can produce a large quantity of products at a low cost and at high speed and thus, a practical method for producing electronic devices has already been studied by some manufacturers.

According to the method of heating and sintering metal ink by using a heating furnace, however, the heating process is a time-consuming process and if the plastic substrate cannot withstand the heating temperature needed for sintering the metal ink, it is unavoidable to sinter at a temperature at which the plastic substrate can withstand, posing a problem that satisfactory conductivity may not be reached.

Thus, as described in Patent Documents 1 to 3, attempts have been made to use and convert a composition (ink) containing nano-particles into a metal wire by photo irradiation.

A method of using light energy or a microwave for heating may be able to heat only an ink portion and is a very good method, but when metal particles themselves are used, a problem that conductivity of an obtained conductive film is not improved satisfactorily, or when copper oxide is used, a problem that the percentage of voids of an obtained conductive film is large or a part of the copper oxide is not reduced and copper oxide particles remain may arise.

In addition, metal or metal oxide particles whose diameter is 1 micrometer or less need to be used for sintering, posing a problem that preparation of such nano-particles costs a lot of money.

Further, Patent Document 4 discloses a technology that forms a conductive pattern on a film substrate having flexibility by pressurizing an adhesive substance filled with conductive fine particles in a distributed manner while heating the adhesive substance, but such a pressurization process cannot be applied to the heating process performed by photo irradiation or microwave irradiation.

### CITATION LIST

### Patent Literature

[Patent Document 1] Japanese Patent Application National Publication No. 2008-522369

[Patent Document 2] WO 2010/110969

[Patent Document 3] Japanese Patent Application National Publication No. 2010-528428

[Patent Document 4] Japanese Patent Application Laid-Open Publication No. 2008-124446

### SUMMARY OF INVENTION

### Technical Problem

In general, a conductive pattern formed on a substrate is considered to have higher performance with increasing conductivity (decreasing volume resistivity). Thus, it is desirable to further improve conductivity of a conductive pattern formed by the conventional technology.

An object of the present invention is to provide a conductive pattern formation method capable of improving conductivity of a conductive pattern which is formed by printing using a metal ink (including ink containing a metal oxide which can be reduced to a metal using a reducing agent).

### Solution to Problem

To achieve the above object, an embodiment of the present invention is a conductive pattern formation method including printing a composition containing metal oxide particles and a reducing agent, and/or metal particles, on a surface of a substrate, heating at least a part of the printed composition by an internal heat generation system so that conductivity is expressed on the heated portion, and pressurizing the portion expressing the conductivity to obtain a conductive pattern.

In the pressurization process, when the portion expressing the conductivity is pressurized, an insulating protection film is simultaneously pressure-sealed on the surface of the substrate on which the conductive pattern is formed.

The internal heat generation system is heating by photo irradiation or heating by microwave irradiation.

A material for the metal particles is gold, silver, copper, aluminum, nickel, or cobalt, and a material for the metal oxide particles is silver oxide, copper oxide, nickel oxide, cobalt oxide, zinc oxide, tin oxide, or indium tin oxide.

The light to be irradiated to the composition is pulsed light having a wavelength of 200 to 3000 nm.

The microwave to be irradiated to the composition has a wavelength of 1 m to 1 mm.

The reducing agent is a polyhydric alcohol or a carboxylic acid. As the polyhydric alcohol, low-molecular-weight polyhydric alcohol such as ethylene glycol and polyglycerin and also polyalkylene glycol can be used.

### Advantageous Effects of Invention

According to the present invention, a conductive pattern formation method capable of improving conductivity of a conductive film can be provided.

### BRIEF DESCRIPTION OF DRAWINGS

FIG. 1 is a process drawing of a method for forming a conductive pattern according to an embodiment of the present invention.

FIG. 2 is a diagram illustrating the definition of pulsed light.

FIG. 3 is a schematic view of a conductive pattern forming apparatus according to an embodiment of the present invention.

FIG. 4 is a diagram showing SEM photos of a conductive film before and after pressing.

FIG. 5 is a diagram showing SEM photos of the conductive film before and after pressing.

FIG. 6 is a diagram showing SEM photos of the conductive film before and after pressing.

FIG. 7 is a diagram showing SEM photos of the conductive film before and after pressing.

FIG. 8 is a diagram illustrating the printing, heating and pressurizing process.

### DESCRIPTION OF EMBODIMENTS

A mode (hereinafter, referred to an embodiment) to carry out the present invention will be described below in accordance with the drawings.

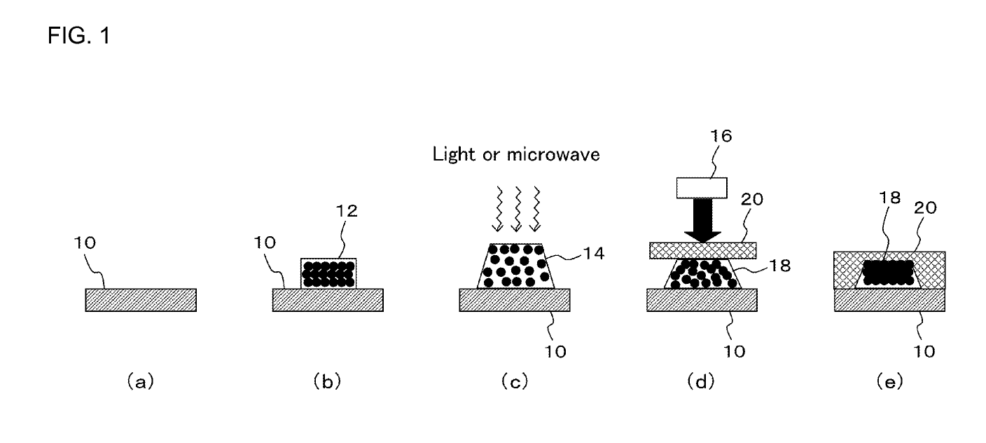

FIGS. 1(a) to 1(e) show process drawings of a conductive pattern formation method according to an embodiment. In FIG. 1, a substrate 10 is prepared (a) and a composition (ink) containing metal particles, and/or metal oxide particles, and a reducing agent is printed on the substrate 10 in a predetermined pattern to form an ink layer 12 (b). There is no specific limitation regarding the shape of the pattern. The pattern may be a wiring pattern or flat uniform pattern. Further, in the present specification, the conductive pattern is a conductive film which is a conductive metallic thin film made of metal formed in a pattern, the film being obtained by forming a composition having metal particles or metal oxide particles dispersed in a binder resin into a printed pattern, and subjecting the printed pattern to photo irradiation to sinter the metal particles or the metal oxide particles.

A substrate used as a printed wiring board or an insulating substrate can be used as the substrate 10 and such a substrate includes a complex substrate such as a ceramic substrate of alumina or the like, glass substrate, paper substrate, paper phenol substrate, and glass epoxy substrate and a film substrate such as a polyimide substrate, polyester substrate, and polycarbonate substrate. In case of the film substrate, if the film is too thin, pressurization cannot be effectively performed. Thus, preferably, the film should be at least 10 micrometer (MIC 10⁻⁶ m) thick, and more preferably, at least 50 micrometer thick.

On a surface of these substrates, surface-treatment such as plasma or corona treatment may be conducted to improve the adhesiveness, or an adhesive resin such as an epoxy resin or polyamic acid may be coated to improve the adhesiveness to ink, when necessary.

Gold, silver, copper, aluminum, nickel, cobalt or the like can be used as the material of metal particles, and silver oxide, copper oxide, nickel oxide, cobalt oxide, zinc oxide, tin oxide, indium tin oxide or the like can be used as the material of metal oxide particles. The reducing agent will be described later.

The particle size of metal particles or metal oxide particles to be used depends on the intended printing accuracy, but if the particle size is too small, it becomes difficult to design the ink mixture and in addition, the specific surface area increases and thus, the amount of protective colloid used for the prevention of aggregation needs to be relatively increased. On the other hand, if the particle size is too large, there are drawbacks that a fine pattern cannot be printed and sintering is difficult due to poor contact between particles. Therefore, with respect to a spherical particle, the particle size is generally selected from 5 nm (nanometer) to 10 micrometer, preferably from 10 nm to 5 micrometer. Flat particles and wire-shaped particles can also be used other than the spherical particles. With respect to the flat particle, the particle thickness is selected from 5 nm to 10 micrometer, preferably from 10 nm to 5 micrometer, the shape of the flat particle is circular or polygonal, and a portion of the flat particle having the shortest length (for example, the diameter when the shape is circular, the minor axis when the shape is ellipsoidal, or the shortest side when the shape is polygonal) has a length of at least from 5 to 1000 times, preferably from 10 to 100 times, of the thickness of the portion. With respect to the wire-shaped particle, the wire diameter is selected from 5 nm to 2 micrometer, preferably from 10 nm to 1 micrometer, and the wire length is selected from 1 micrometer to 200 micrometer, preferably from 2 micrometer to 100 micrometer.

Regarding the physical property of the metal (in case of an oxide, the reduced metal) used herein, a lower elastic modulus is preferable because deformation becomes easier. However, if the elastic modulus is too low, a practically sufficient strength cannot be ensured. The elastic modulus in terms of Young's modulus is preferably from 30×10⁹ N/m² to 500×10⁹ N/m², more preferably from 50×10⁹ N/m² to 300×10⁹ Nm².

In case of the spherical particle, the particle size means an average particle size D50 (median diameter) of the number standard that can be measured by the laser diffraction/scattering method or the dynamic light scattering method. In case of the flat particle or the wire-shaped particle, the particle size means a size measured by SEM observation.

Further, as a matter of course, when the ink is printed, it is preferable that the particle density of the coated portion after the printing is as uniform as possible.

Next, the ink layer 12 is heated by photo irradiation or microwave irradiation as the internal heat generation system so that conductivity is expressed on the heated portion by heating to convert the ink layer 12 into a conductive layer 14 (c). In the internal heat generation system, metal particles and/or metal oxide particles in the ink are heated and the substrate 10 is not heated and thus, even if the substrate 10 made of plastics is used, the substrate 10 can be prevented from being deformed. Therefore, the ink layer 12 can be heated until conductivity is expressed sufficiently in the ink layer 12. Light and the microwave irradiated to the ink layer 12 will be described later.

When the ink layer 12 is irradiated with light or the microwave in process (c), metal particles and/or metal oxide particles are heated quickly in a short time and air bubbles are generated, which makes voids inside the conductive layer 14 converted from the ink layer 12 more likely to be generated. The generation mechanism and aspect of the voids are different to some extent between the case when the metal oxide particles are used and the case when the metal particles are used. When the metal oxide particles are used, continuous sintered bodies of the metal are generated, and due to the gas generated at the time of reduction, voids are generated. On the other hand, when the metal particles are used, conductivity is expressed due to necking of the particles, and the spaces remained between the particles form voids. In either case, in the present embodiment, the conductive layer 14 expressing the conductivity is pressurized by an appropriate pressing machine 16 to crush voids present inside the conductive layer 14 so that a conductive pattern 18 is obtained by improving the conductivity of the conductive layer 14 (d). The method of pressing is not limited and a method of applying surface pressurization by fixing the substrate 10 obtained in process (c) and on which the conductive layer 14 is formed to a hard plane and moving a pressurization point to which point pressure is applied by a hard bar, a method of pressurizing a whole surface by sandwiching the substrate 10 between two rolls to apply linear pressure and rotating the rolls, a method of pressurizing by sandwiching the substrate 10 between two flat plates and using an ordinary pressing device as a batch method, and the like can be cited.

When pressurizing the conductive pattern 18 in process (d), an insulating protection film 20 may simultaneously be pressure-sealed on the surface of the substrate on which the conductive pattern 18 is formed. Accordingly, as shown in FIG. 1E, the conductive pattern 18 is covered with the insulating protection film 20 so that oxidation of the conductive pattern 18 can be prevented and decrease in conductivity of the conductive pattern 18 can be inhibited.

In the example shown in FIGS. 1D and 1E, the conductive pattern 18 is formed on one side of the substrate 10, but the conductive patterns 18 can be formed on both sides of the substrate 10 while controlling the formation positions of the conductive patterns 18 and the insulating protection films 20 can be pressure-sealed on both sides.

As the reducing agent used for the ink, an alcohol compound such as methanol, ethanol, isopropyl alcohol, butanol, cyclohexanol, and terpineol, polyhydric alcohol such as ethylene glycol, propylene glycol, and glycerin, carboxylic acid such as formic acid, acetic acid, oxalic acid, and succinic acid, a carbonyl compound such as acetone, methyl ethyl ketone, benzaldehyde, and octyl aldehyde, an ester compound such as ethyl acetate, butyl acetate, and phenyl acetate, or a hydrocarbon compound such as hexane, octane, toluene, naphthaline, decalin, and cyclohexane can be used. Among them, in consideration of efficiency of the reducing agent, polyhydric alcohol such as ethylene glycol, propylene glycol, and glycerin or carboxylic acid such as formic acid, acetic acid, and oxalic acid is suitable.

It is necessary for a binder resin to use a conductive pattern formation composition containing metal particles and/or metal oxide particles is used as ink, and a binder resin acting also as a reducing agent may be used. A poly-N-vinyl compound such as polyvinyl pyrrolidone and polyvinyl caprolactam, a polyalkylene glycol compound such as polyethylene glycol, polypropylene glycol, and poly THF, a thermoplastic resin and a thermosetting resin such as polyurethane, a cellulose compound and derivatives thereof, an epoxy compound, a polyester compound, chlorinated polyolefin, and a polyacrylic compound, can be used as a polymeric compound acting also as a reducing agent. Among them, polyvinyl pyrrolidone is preferable in consideration of the binder effect and polyethylene glycol, polypropylene glycol, or polyurethane compound is preferable in consideration of the reduction effect. Incidentally, polyethylene glycol and polypropylene glycol are classified into polyhydric alcohol and particularly have properties suitable as a reducing agent.

The presence of a binder resin is indispensable, but using a large quantity of binder resin causes a problem of making the expression of conductivity less likely and if the amount thereof is too small, the capability of binding particles becomes low. Therefore, the amount of binder resin of 1 to 50 mass parts, preferably 3 to 20 mass parts to 100 mass parts of the total amount of metal particles and/or metal oxide particles is preferable.

The solvent to be used depends on the intended printing method, and publicly known organic solvents, a water solvent or the like can be used.

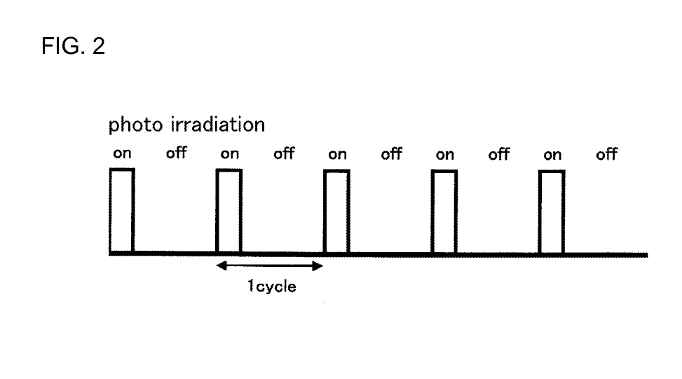

Pulsed light of the wavelength 200 nm to 3000 nm can be used as light to be irradiated to the ink layer 12. “Pulsed light” herein means light whose photo irradiation period (irradiation time) ranges from a few microseconds to a few tens of milliseconds, and when photo irradiation is repeated a plurality of times, as shown in FIG. 2, a period without photo irradiation (irradiation interval (off)) is present between a first photo irradiation period (on) and a second photo irradiation period (on). While light intensity of the pulsed light appears to be constant in FIG. 2, the light intensity in one photo irradiation period (on) may change. The pulsed light is emitted from a light source including a flash lamp such as a xenon flash lamp. Pulsed light is irradiated to the ink layer 12 by using such a light source. When irradiation is repeated n times, one cycle (on+off) in FIG. 2 is repeated n times. When irradiation is repeated, it is preferable to cool before the next pulsed light irradiation from the side of substrate so that the substrate can be cooled down to the room temperature.

The range of about 20 microseconds to about 10 milliseconds is preferable as one irradiation time (on) of pulsed light. When the irradiation time (on) is shorter than 20 microseconds, sintering does not proceed and the effect of performance improvement of a conductive pattern decreases. When the irradiation time (on) is longer than 10 milliseconds, adverse effects due to light degradation and heat degradation predominate. Single irradiation of pulsed light has an effect, but as described above, irradiation can be repeated.

The ink layer 12 can also be heated by a microwave. When the ink layer 12 is heated by a microwave, the microwave to be used is an electromagnetic wave whose wavelength range is 1 m to 1 mm (the frequency ranges from 300 MHz to 300 GHz).

The material used for the insulating protection film 20 is not specifically limited and a publicly known coating material including a thermoplastic resin, photo-curing resin, and thermosetting resin, such as a polyimide resin, polyester resin, cellulose resin, vinyl alcohol resin, vinyl chloride resin, vinyl acetate resin, cycloolefin resin, polycarbonate resin, acrylic resin, epoxy resin, polyurethane resin, ABS resin, and the like can be used. The thickness of the insulating protection film 20 is preferably 1 micrometer or more and 188 micrometer or less and particularly preferably 5 micrometer or more and 100 micrometer or less. On a surface of the protection film, surface-treatment such as plasma or corona treatment can be conducted to improve the adhesiveness, or an adhesive resin such as an epoxy resin or polyamic acid may be coated to improve the adhesiveness to ink.

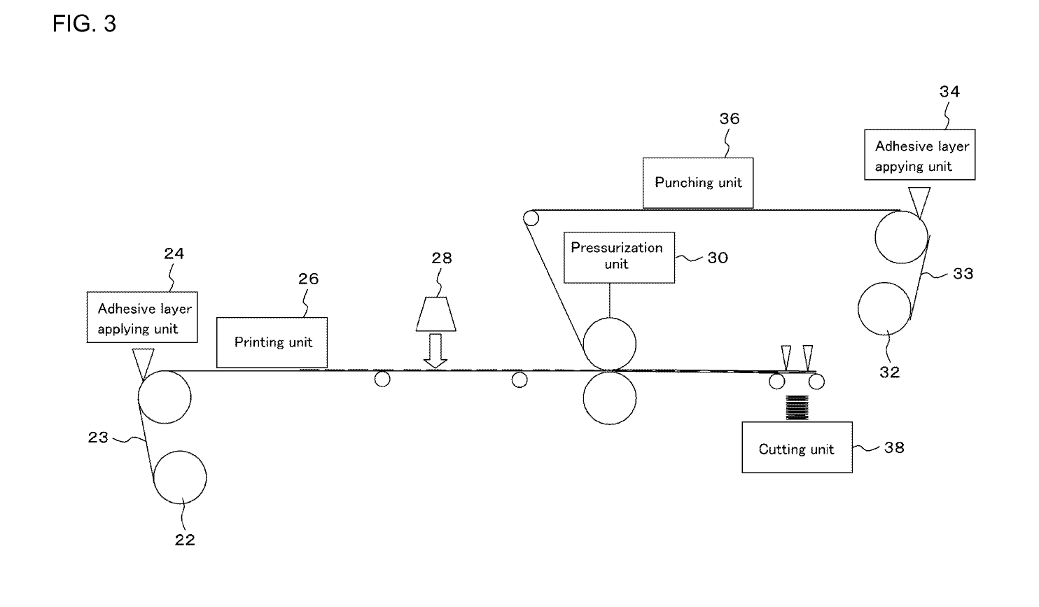

FIG. 3 shows a schematic view of a conductive pattern forming apparatus according to the present embodiment. In FIG. 3, a plastic film 23 is supplied from a roll 22 of a plastic film to form the substrate 10 and an appropriate adhesive is applied to a predetermined position of the plastic film 23 by an adhesive layer applying unit 24. The ink is printed in a predetermined pattern by a printing unit 26 on the predetermined position of the plastic film 23 to which the adhesive has been applied to form the ink layer 12. The ink layer 12 is heated by a heating unit 28 that heats a target by an internal heat generation system through photo irradiation or microwave irradiation to form the conductive layer 14. Then, the plastic film 23 with the formed conductive layer 14 is supplied to a pressurization unit 30 configured by a press roll.

On the other hand, an insulating film 33 is supplied from a roll 32 of an insulating film to be the insulating protection film 20 and an appropriate adhesive is applied to a predetermined position of the insulating film 33 by an adhesive layer applying unit 34. Next, the insulating film 33 whose corresponding portion necessary for electrification of a printed circuit (conductive layer 14) is punched by a punching unit 36 is supplied to the pressurization unit 30.

The pressurization unit 30 aligns the plastic film 23 and the insulating film 33 and pressurizes both by the press roll configuring the pressing unit 30 to laminate the insulating film 33 by the adhesive to the surface on which the conductive layer 14 of the plastic film 23 is formed. At this point, the conductive layer 14 is pressurized by the press roll to crush voids present inside the conductive layer 14.

The pressure during pressurization by the pressurization unit 30 is not specifically limited as long as the conductive layer 14 is thereby deformed, but when pressure-sealed by a press roll, the linear pressure is preferably 1 kgf/cm (980 Pa*m) or more and 100 kgf/cm (98 kPa*m) or less and particularly preferably 10 kgf/cm (9.8 kPa*m) or more and 50 kgf/cm (49 kPa*m) or less. The feed speed (line speed) of the substrate (the plastic film 23 and the insulating film 33) can appropriately be selected from a practical range and in general, the feed speed is preferably 10 mm/min or more and 10000 mm/min or less and particularly preferably 10 mm/min or more and 100 mm/min or less. This is because if the feed speed is too fast, a sufficient pressurization time cannot be obtained. However, the number of times of pressure-bonding can be increased by increasing the number of press rolls and the feed speed can be made faster by increasing the pressurization time.

In the case of being pressurized by sandwiching between two flat plates using an ordinary pressing device, pressure uniformity is inferior to in the case of using a press roll but it is possible to use an ordinary pressing device. The pressure is preferably from 0.1 to 200 MPa, and more preferably from 1 to 100 MPa.

Moreover, heating can be performed during the pressurization to make the bonding stronger. Due to the pressurization, the volume resistivity is decreased, and also, the mechanical property such as a bending strength, can be increased. Essentially, the increasing pressure provides higher effect in the reduction of the volume resistivity and the improvement of the mechanical strength. However, when the pressure is too high, the cost for the pressurization apparatus becomes extremely high, while the obtained effect is not so high, and the substrate itself may be damaged. Accordingly, the aforementioned upper limit value is preferable.

Lastly, the plastic film 23 and the insulating film 33 are cut by a cutting unit 38 to finish the product.

According to the embodiment shown in FIG. 3, a conductive pattern can be formed, as described above, by the continuous process.

### EXAMPLES

Examples of the present invention will concretely be described below. The Examples described below are intended to make the understanding of the present invention easier and the present invention is not limited to such Examples.

In the Examples and Comparative Examples below, the volume resistivity was measured by LorestaGP manufactured by Mitsubishi Chemical Analytech Co., Ltd. and FE-SEM S-5200 manufactured by Hitachi High-Technologies Corporation was used as the SEM for photographing. The laser diffraction/scattering method (microtrack grain size distribution measuring device MT3000II series USVR manufactured by Nikkiso Co., Ltd.) was used for measurement of the average particle size D50 (median diameter) of the number standard of particles when the particle size was 500 nm or more, and the dynamic scattering method (nanotrack UPA-EX150 manufactured by Nikkiso Co., Ltd.) was used for measurement when the particle size was less than 500 nm to determine the particle size by a spherical approximation.

### Example 1

A binder solution of 40% by weight was prepared by dissolving polyvinyl pyrrolidone (manufactured by Nippon Shokubai Co., Ltd.) as a binder in a mixed aqueous solution (ethylene glycol:glycerin:water=70:15:15 in weight ratio) of ethylene glycol and glycerin (reagents manufactured by Kanto Chemical Co., Inc.) as reducing agents. 1.5 g of this solution and 0.5 g of the above mixed aqueous solution were mixed and further 6.0 g of N300 (average particle size D50=470 nm) manufactured by Tokusen Kogyo., Ltd. as silver particles is mixed and Planetary Centrifugal Vacuum Mixer THINKY MIXER ARV-310 (AWATORI RENTARO) (manufactured by Thinky Corporation) is used to mix the solution well to produce a paste for printing.

The obtained paste was printed on a polyimide film (Kapton 100V manufactured by Du Pont/Toray Co., Ltd., thickness: 25 micrometer) as a pattern of 2 cm square by screen printing to a thickness of 9 micrometer. Pulsed light was irradiated to the sample obtained as described above by using Sinteron3300 manufactured by Xenone to convert the pattern into a conductive pattern. Under the irradiation conditions that the pulse width was set to 2000 microseconds, the voltage was set to 3000 V, and single irradiation was applied from an irradiation distance of 20 cm, the pulse energy at this point was 2070 J. The thickness of the conductive pattern formed as described above was 24 micrometer and the volume resistivity thereof was 1.34×10⁻⁴ ohm*cm.

A polyimide film (Kapton 100V manufactured by Du Pont/Toray Co., Ltd., thickness: 25 micrometer) was placed on the obtained conductive pattern to press the polyimide film at 10 MPa for 60 seconds (by Mini test press MP-SCL manufactured by Toyo Seiki Seisaku-Sho, Ltd.) by sandwiching between two 20-cm-square mirror-finished stainless plates each having a thickness of 5 mm to obtain a conductive pattern. The thickness of the conductive pattern after pressing was 14 micrometer and the volume resistivity thereof was 6.82×10⁻⁵ ohm*cm. The result is shown in Table 1.

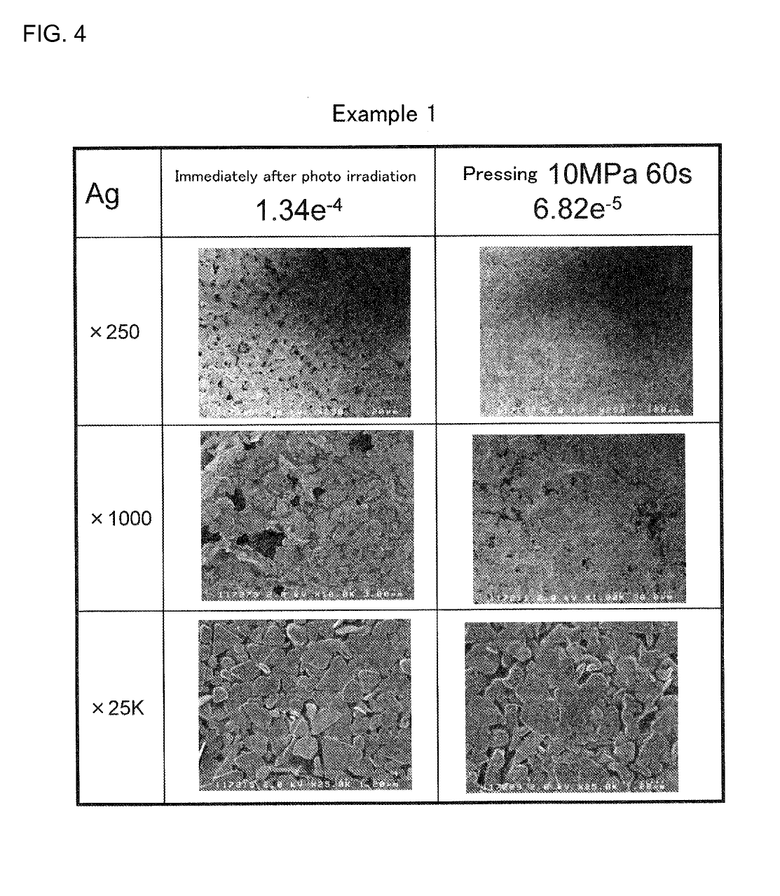

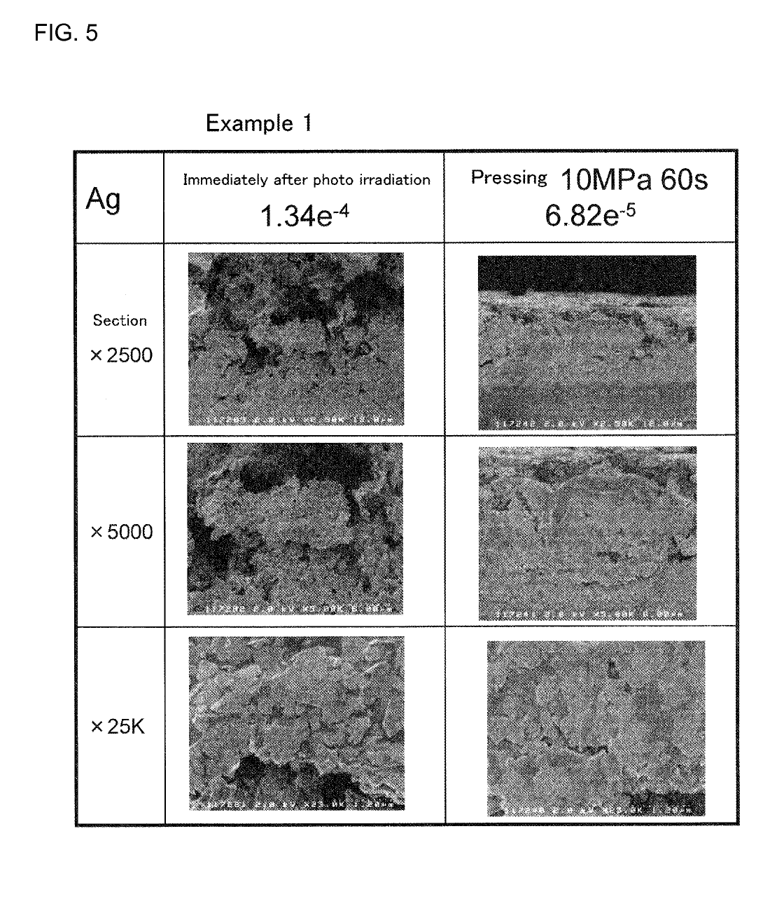

FIGS. 4 and 5 show SEM photos of the conductive pattern before and after pressing. FIG. 4 shows 250×, 1000×, and 25000× plane photos and FIG. 5 shows 2500×, 5000×, and 25000× sectional photos. It is clear that many voids are crushed after pressing compared to before pressing (described as immediately after photo irradiation). The sequence of work described above was done in the atmosphere.

### Example 2

A binder solution of 40% by weight was prepared by dissolving polyvinyl pyrrolidone (manufactured by Nippon Shokubai Co., Ltd.) as a binder in a mixed aqueous solution (ethylene glycol:glycerin:water=70:15:15 in weight ratio) of ethylene glycol and glycerin (reagents manufactured by Kanto Chemical Co., Inc.) as reducing agents. 1.5 g of this solution and 0.5 g of the above mixed aqueous solution were mixed and further 6.0 g of copper particles 1050Y (average particle size D50=716 nm) manufactured by Mitsui Mining & Smelting Co., Ltd. was mixed and Planetary Centrifugal Vacuum Mixer THINKY MIXER ARV-310 (AWATORI RENTARO) (manufactured by Thinky Corporation) was used to mix the solution well to produce a paste for printing.

The obtained paste was printed on a polyimide film (Kapton 100V manufactured by Du Pont/Toray Co., Ltd., thickness: 25 micrometer) as a pattern of 2 cm square by screen printing to a thickness of 10 micrometer. Pulsed light was irradiated to the sample obtained as described above by using Sinteron3300 manufactured by Xenone to convert the pattern into a conductive pattern. Under the irradiation conditions that the pulse width was set to 2000 microseconds, the voltage was set to 3000 V, and single irradiation was applied from the irradiation distance of 20 cm, the pulse energy was 2070 J. The thickness of the conductive pattern formed as described above was 22 micrometer and the volume resistivity thereof was 3.45×10⁻² ohm*cm.

A polyimide film (Kapton 100V manufactured by Du Pont/Toray Co., Ltd., thickness: 25 micrometer) was placed on the obtained conductive pattern to press the polyimide film at 10 MPa for 60 seconds to obtain a conductive pattern in the same manner as in Example 1. The thickness of the conductive pattern after pressing was 16 micrometer and the volume resistivity thereof was 5.33×10⁻³ ohm*cm. The result is shown in Table 1.

### Example 3

A binder solution of 40% by weight was prepared by dissolving polyvinyl pyrrolidone (manufactured by Nippon Shokubai Co., Ltd.) as a binder in a mixed aqueous solution (ethylene glycol:glycerin:water=70:15:15 in weight ratio) of ethylene glycol and glycerin (reagents manufactured by Kanto Chemical Co., Inc.) as reducing agents. 1.5 g of this solution and 0.5 g of the above mixed aqueous solution were mixed and further 6.0 g of NanoTek CuO (average particle size D50=270 nm) manufactured by C. I. Kasei Co., Ltd. was mixed and Planetary Centrifugal Vacuum Mixer THINKY MIXER ARV-310 (AWATORI RENTARO) (manufactured by Thinky Corporation) was used to mix the solution well to produce a paste for printing.

The obtained paste was printed on a polyimide film (Kapton 100V manufactured by Du Pont/Toray Co., Ltd., thickness: 25 micrometer) as a pattern of 2 cm square by screen printing to a thickness of 9 micrometer. Pulsed light was irradiated to the sample obtained as described above by using Sinteron3300 manufactured by Xenone to convert the pattern into a conductive pattern. Under the irradiation conditions that the pulse width was set to 2000 microseconds, the voltage was set to 3000 V, and single irradiation was applied from the irradiation distance of 20 cm, the pulse energy was 2070 J. The thickness of the conductive pattern formed as described above was 17 micrometer and the volume resistivity thereof was 1.29×10⁻⁴ ohm*cm.

A polyimide film (Kapton 100V manufactured by Du Pont/Toray Co., Ltd., thickness: 25 micrometer) was placed on the obtained conductive pattern to press the polyimide film at 10 MPa for 60 seconds to obtain a conductive pattern in the same manner as in Example 1. The thickness of the conductive pattern after pressing was 11 micrometer and the volume resistivity thereof is 9.17×10⁻⁵ ohm*cm. The result is shown in Table 1.

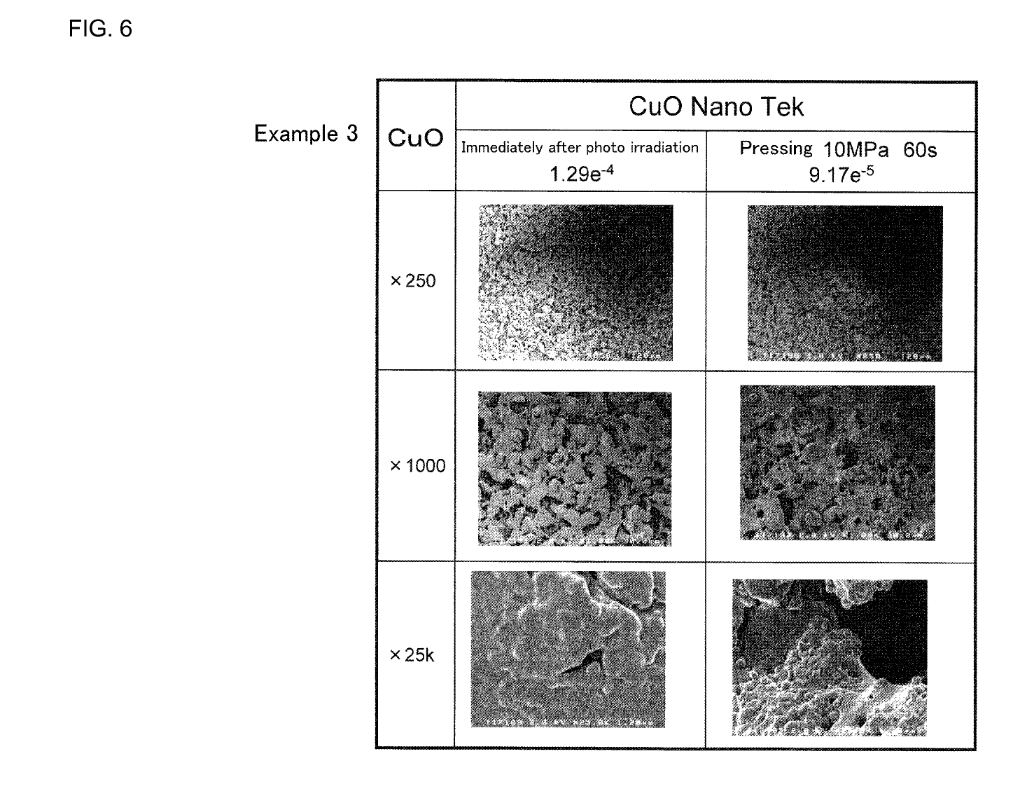

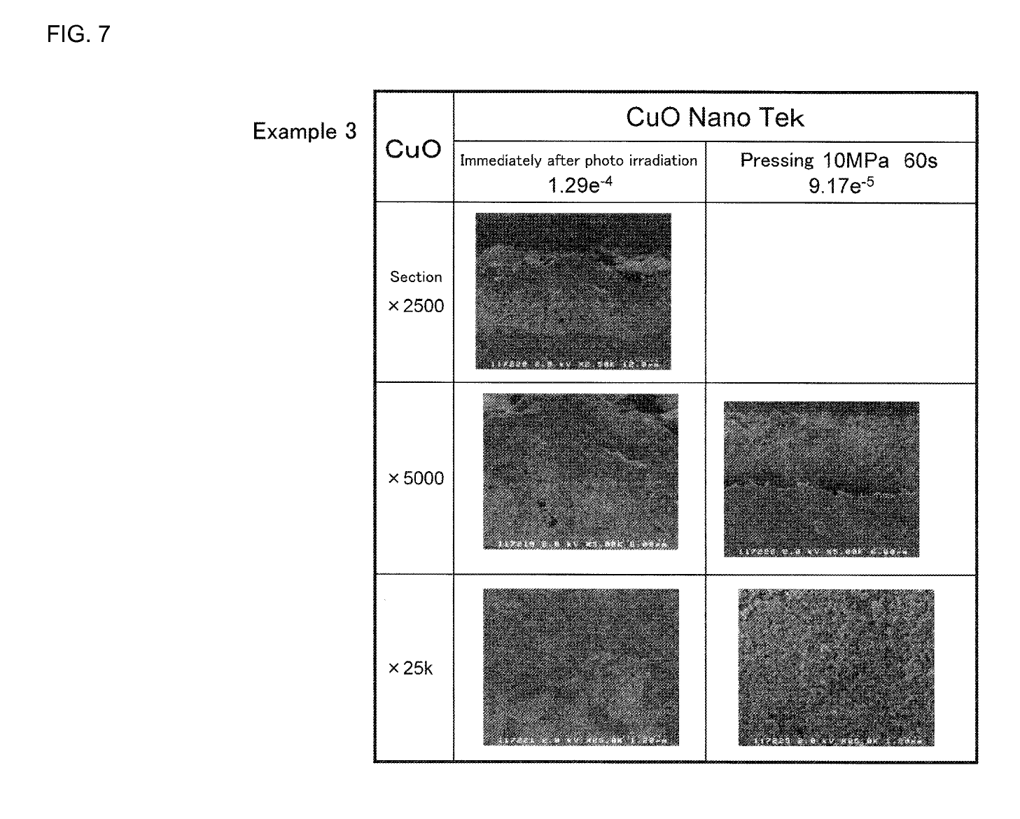

FIGS. 6 and 7 show SEM photos of the conductive film before and after pressing. FIG. 6 shows 250×, 1000×, and 25000× plane photos and FIG. 7 shows 2500×, 5000×, and 25000× sectional photos. It is clear that many voids are crushed after pressing compared to before pressing (described as immediately after photo irradiation).

### Example 4

A binder solution of 40% by weight was prepared by dissolving polyvinyl pyrrolidone (manufactured by Nippon Shokubai Co., Ltd.) as a binder in a mixed aqueous solution (ethylene glycol:glycerin:water=70:15:15 in weight ratio) of ethylene glycol and glycerin (reagents manufactured by Kanto Chemical Co., Inc.) as reducing agents. 1.5 g of this solution and 0.5 g of the above mixed aqueous solution were mixed and further 5.4 g of copper particles 1020Y (average particle size D50=380 nm) manufactured by Mitsui Mining & Smelting Co., Ltd. and 0.6 g of NanoTek CuO (average particle size D50=270 nm) manufactured by C. I. Kasei Co., Ltd. were mixed as copper oxide particles (copper particles:copper oxide particles=90:10) and Planetary Centrifugal Vacuum Mixer THINKY MIXER (AWATORI RENTARO) ARV-310 (manufactured by Thinky Corporation) was used to mix the solution well to produce a paste for printing.

The obtained paste was printed on a polyimide film (Kapton 100N manufactured by Du Pont/Toray Co., Ltd., thickness: 25 micrometer) as a pattern of 2 cm square by screen printing to a thickness of 12 micrometer. Pulsed light was irradiated to the sample obtained as described above by using Sinteron3300 manufactured by Xenone to convert the pattern into a conductive pattern. Under the irradiation conditions that the pulse width was set to 2000 microseconds, the voltage was set to 3000 V, and single irradiation was applied from the irradiation distance of 20 cm, the pulse energy was 2070 J. The thickness of the conductive pattern formed as described above was 24 micrometer and the volume resistivity thereof was 2.43×10⁻⁴ ohm*cm.

A polyimide film (Kapton 100V manufactured by Du Pont/Toray Co., Ltd., thickness: 25 micrometer) was placed on the obtained conductive layer to press the polyimide film at 10 MPa for 60 seconds to obtain a conductive pattern in the same manner as in Example 1. The thickness of the conductive pattern after pressing was 13 micrometer and the volume resistivity thereof was 1.35×10⁻⁴ ohm*cm. The result is shown in Table 1.

### Example 5

Copper oxide ink ICI-020 (copper oxide average grain size D50=192 nm) manufactured by NovaCentrix was printed on a polyimide film (Kapton 100V manufactured by Du Pont/Toray Co., Ltd., thickness: 25 micrometer) as a pattern of 2 cm square by screen printing to a thickness of 11 micrometer. Pulsed light was irradiated to the sample obtained as described above by using Sinteron3300 manufactured by Xenone to convert the pattern into a conductive pattern. Under the irradiation conditions that the pulse width was set to 2000 microseconds, the voltage was set to 3000 V, and single irradiation was applied from the irradiation distance of 20 cm, the pulse energy at this point was 2070 J. The thickness of the conductive pattern formed as described above was 23 micrometer and the volume resistivity thereof was 3.22×10⁻⁴ ohm*cm.

A polyimide film (Kapton 100V manufactured by Du Pont/Toray Co., Ltd., thickness: 25 micrometer) was placed on the obtained conductive pattern to press the polyimide film at 10 MPa for 60 seconds to obtain a conductive pattern in the same manner as in Example 1. The thickness of the conductive pattern after pressing was 16 micrometer and the volume resistivity thereof was 9.27×10⁻⁵ ohm*cm. The result is shown in Table 1.

### Example 6

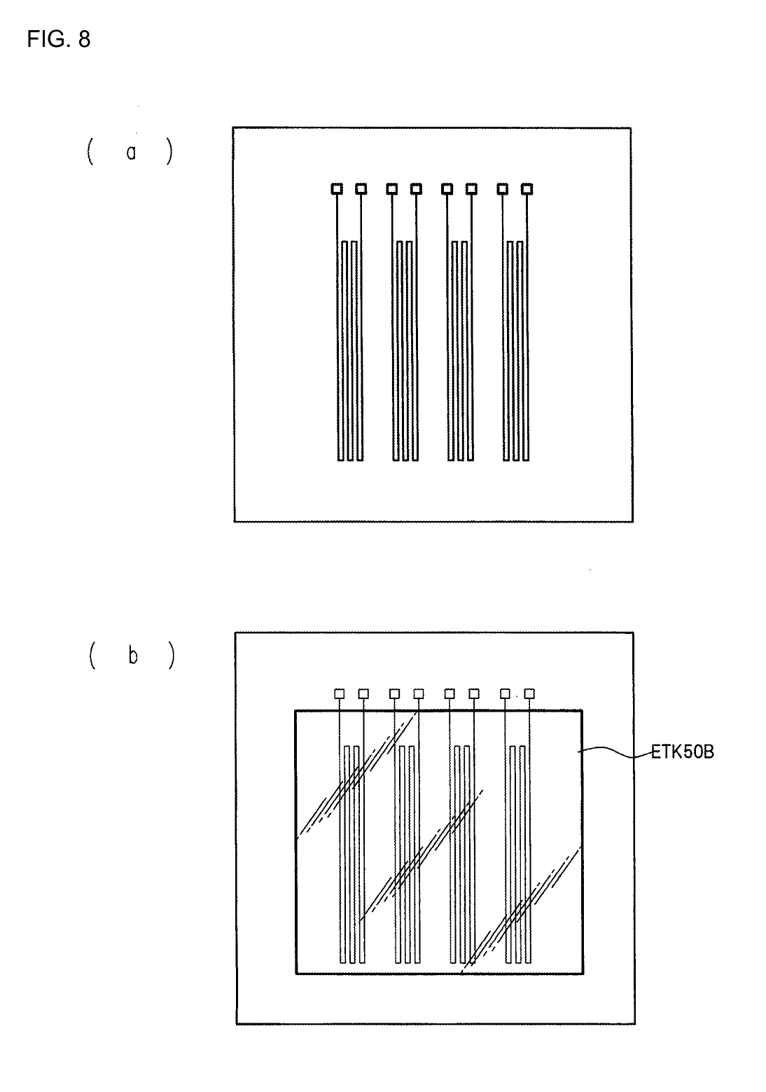

The paste obtained by Example 1 was printed on a polyimide film (Kapton 100V manufactured by Du Pont/Toray Co., Ltd., thickness: 25 micrometer) to a thickness of 5 micrometer as a pattern shown in FIG. 8(a). Pulsed light was irradiated to the sample obtained as described above by using Pulse Forge 3300 manufactured by Novacentrix to convert the printed pattern into a conductive pattern. Under the irradiation conditions that the pulse width was set to 900 microseconds, the voltage was set to 350 V, and single irradiation was applied while placing the sample on a conveyor of the apparatus, the pulse energy was 5630 J/m². The thickness of the conductive pattern formed as described above was 12 micrometer, and the resistance between terminals at the opposite ends was 19 ohms, when measured by a tester (DIGITAL MULTIMETER PC5000a RS-232C, manufactured by Sanwa Electric Instrument Co., Ltd.).

As shown in FIG. 8(b), Panaprotect ETK50B (manufactured by Panac Corporation, acrylic adhesive layer, thickness: 5 micrometer, and PET substrate, thickness: 50 micrometer) was cut out and placed on the sample obtained as described above so that the adhesive surface was brought into contact with the printed surface, to press the sample at 10 MPa for 60 seconds (by Mini test press MP-SCL manufactured by Toyo Seiki Sesaku-sho, Ltd.) by sandwiching between two 20-cm-square mirror-finished stainless plates each having a thickness of 5 mm. The resistance between terminals at the opposite ends of the obtained sample was 12 ohms, when measured by a tester.

The sample subjected to irradiation only, and the sample subjected to irradiation and pressing, were further subjected to a folding endurance test by a MIT tester (No. 702 MIT type folding endurance tester, Product No. H9145, manufactured by Mys-Tester Co., Ltd.), under the conditions that the test load was 500 g, the folding angle was 90 degrees, and the curvature radius was R0.38 mm. Even after 100,000 times of folding endurance tests, circuit breakage did not occur in either of the samples. However, the resistance value was changed during the folding endurance tests in the sample which was irradiated but not pressed, whereas there was almost no change in the resistance value of the sample which was irradiated and pressed, leading to the findings that the strength of the circuit was increased.

### Comparative Example 1

The paste in Example 2 was printed on a polyimide film (Kapton 100V manufactured by Du Pont/Toray Co., Ltd., thickness: 25 micrometer) as a pattern of 2 cm square by screen printing. The sample obtained in this manner was heated in an oven at 250 degree C. in the air for one hour. Though densely packed copper particles were suggested by the thickness 11 micrometer of the obtained pattern, the volume resistivity was a value of 10⁶ ohm*cm or more.

A polyimide film (Kapton 100V manufactured by Du Pont/Toray Co., Ltd., thickness: 25 micrometer) was placed on the conductive pattern to press the polyimide film at 10 MPa for 60 seconds in the same manner as in Example 1. As a result, the pattern thickness changes to 9 micrometer, but the volume resistivity did not change. The result is shown in Table 1.

### Comparative Example 2

Instead of heating by an oven at 250 degree C., the sample printed in the same manner as in Comparative Example 1 was pressed at 250 degree C. and 10 MPa for 60 seconds in the same manner as in Example 1. As a result, the pattern thickness changes to 8 micrometer, but the volume resistivity was 10⁶ ohm*cm or more. The result is shown in Table 1.

As shown in Table 1, the pattern thickness after pulsed light irradiation was thicker than that before pulsed light irradiation in all cases of Examples 1 to 5. This is because voids are generated inside the conductive pattern by rapid heating caused by pulsed light irradiation.

TABLE 1

| | | | Before | After irradiation | | After pressing | |
|---|---|---|---|---|---|---|---|
| | | | irradiation | | Volume | | Volume |
| | | | Thickness | Thickness | resistivity | Thickness | resistivity |
| | Metal type | D50 (nm) | (μm) | (μm) | (Ω · cm) | (μm) | (Ω · cm) |
| Example 1 | Ag(N300) | 470 | 9 | 24 | 1.34E−04 | 14 | 6.82E−05 |
| Example 2 | Cu 1050Y | 716 | 10 | 22 | 3.45E−02 | 16 | 5.33E−03 |
| Example 3 | CuO Nano Tek | 270 | 9 | 17 | 1.29E−04 | 11 | 9.17E−05 |
| Example 4 | 1020Y + | 1020Y: | 12 | 24 | 2.43E−04 | 13 | 1.35E−04 |
| | NanoTek | 380 | | | | | |
| | CuO10% | CuO: | | | | | |
| | | 270 | | | | | |
| Example 5 | CuO ICI-20 | 192 | 11 | 23 | 3.22E−04 | 16 | 9.27E−05 |
| Comparative | Cu 1050Y | 716 | | 11 | >1.00E+06 | 9 | >1.00E+06 |
| Example 1 | | | | | | | |
| Comparative | Cu 1050Y | 716 | | | | 8 | >1.00E+06 |
| Example 2 | | | | | | | |

Comparative Example 1 shows the thickness and volume resistivity before and after pressing when heated by an oven without photo irradiation.

Comparative Example 2 shows the thickness and volume resistivity when heating and pressing are carried out simultaneously without photo irradiation.

On the other hand, as shown in Examples 1 to 5, the conductive pattern thickness becomes thinner than before pressing in all cases by crushing voids by pressing and conductivity of the conductive pattern is improved (lower volume resistivity) in all cases.

In Comparative Examples 1, 2 in which the same paste as that in Example 2 was used, no improvement of conductivity is observed. This is because the generation of voids is reduced in a system simply heated in the air by taking time, but surface oxidation takes precedence and sintering between copper particles cannot be carried out properly unlike the case of pulsed light irradiation.

### REFERENCE SIGNS LIST

10 substrate, 12 ink layer, 14 conductive layer, 16 pressing machine, 18 conductive pattern, 20 insulating protection film, 22 and 32 roll, 23 plastic film, 24 adhesive layer applying unit, 26 printing unit, 28 heating unit, 30 pressurization unit, 33 insulating film, 34 adhesive layer applying unit, 36 punching unit, 38 cutting unit

1. A conductive pattern formation method comprising:
printing a composition containing metal oxide particles and a reducing agent, and/or metal particles, on a surface of a substrate;
heating at least a part of the printed composition by an internal heat generation system so that conductivity is expressed on the heated portion; and
pressurizing the portion expressing the conductivity to obtain a conductive pattern.

2. A conductive pattern formation method according to claim 1, when the portion expressing the conductivity is pressurized, an insulating protection film is simultaneously pressure-sealed on the surface of the substrate on which the conductive pattern is formed.

3. A conductive pattern formation method according to claim 1, wherein the internal heat generation system is heating by photo irradiation or heating by microwave irradiation.

4. A conductive pattern formation method according to claim 1, wherein a material for the metal particles is gold, silver, copper, aluminum, nickel, or cobalt, and a material for the metal oxide particles is silver oxide, copper oxide, nickel oxide, cobalt oxide, zinc oxide, tin oxide, or indium tin oxide.

5. A conductive pattern formation method according to claim 1, wherein the light to be irradiated to the composition is pulsed light having a wavelength of 200 to 3000 nm.

6. A conductive pattern formation method according to claim 1, wherein the microwave to be irradiated to the composition has a wavelength of 1 m to 1 mm.

7. A conductive pattern formation method according to claim 1, wherein the reducing agent is a polyhydric alcohol or a carboxylic acid.

8. A conductive pattern formation method according to claim 7, wherein the polyhydric alcohol is polyalkylene glycol.
